(19) United States
(12) Patent Application Publication
(10) Pub. No.: US 2025/0336466 A1
(43) Pub. Date: Oct. 30, 2025

(54) ERROR RATE BASED READ LEVEL ADJUSTMENT TRIGGERING

(71) Applicant: Micron Technology, Inc., Boise, ID (US)

(72) Inventors: Tomer Eliash, Sunnyvale, CA (US); Steven Michael Kientz, Westminster, CO (US); Zhengang Chen, San Jose, CA (US)

(21) Appl. No.: 19/186,788

(22) Filed: Apr. 23, 2025

Related U.S. Application Data
(60) Provisional application No. 63/638,727, filed on Apr. 25, 2024.

(51) Int. Cl. G11C 29/52; G11C 16/26; G11C 16/32; G11C 16/34

(52) U.S. Cl. CPC G11C 29/52; G11C 16/26; G11C 16/32; G11C 16/3404

(57) ABSTRACT

The disclosed memory sub-system controller triggers read level voltage correction for reading a second portion of a memory based on errors encountered while reading data from a first portion of the memory. The controller reads a first portion of data from a first portion of a set of memory components using a set of read threshold levels and determines a read bit error rate (RBER) associated with the data read from the first portion of the set of memory components. The controller determines that the RBER associated with the data read from the first portion transgresses a threshold RBER. The controller selects an individual read level correction process from a plurality of read level correction processes and reads a second portion of data from a second portion of the set of memory components using the set of read threshold levels adjusted based on the selected individual read level correction process.

### PRIORITY APPLICATION

This application claims the benefit of priority to U.S. Provisional Application Ser. No. 63/638,727, filed Apr. 25, 2024, which is incorporated herein by reference in its entirety.

### TECHNICAL FIELD

This disclosure relates generally to memory sub-systems and, more specifically, to providing adaptive media management for memory components, such as memory dies.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 is a block diagram illustrating an example computing environment including a memory sub-system, in accordance with some examples.

FIG. 2 is a block diagram of an example media operations manager, in accordance with some examples.

FIG. 3 is a block diagram of a read bit error rate (RBER) threshold computation process, in accordance with some examples.

FIG. 4 is a flow diagram of an example method to selectively compute a read threshold voltage for certain portions of a memory component, in accordance with some examples.

FIG. 5 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

Aspects of the present disclosure configure a system component, such as a memory sub-system controller, to read data from a first portion of a memory sub-system using read threshold voltages and dynamically and selectively triggering one or more read level correction processes based on the RBER associated with the read data. The memory sub-system controller can select between either performing valley track operations or block family (BF) scan operations as the read level correction process in response to the RBER transgressing an RBER threshold. Namely, rather than waiting to perform the BF scan at previously scheduled periodic intervals or the valley track operations when the RBER is much greater than the RBER threshold, the controller can actively trigger performing one of these processes in response to the RBER transgressing the threshold. This enables the controller to read data from a second portion of the memory sub-system with adjusted read levels resulting from prior read operations. This ensures that performance of the memory system remains optimal by controlling when complex read threshold voltage computation operations (e.g., valley track operations) and BF scan operations are performed. This improves the overall efficiency of operating the memory sub-system and reduces memory resource consumption.

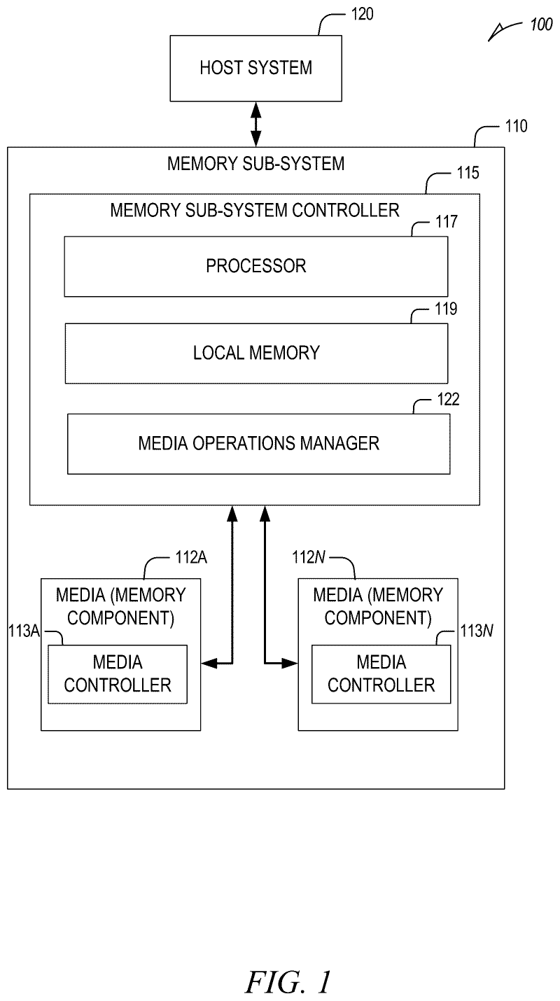

A memory sub-system can be a storage device, a memory module (or component), or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written as part of garbage collection or folding operations (for example, as initiated by the firmware) is hereinafter referred to as “garbage collection data.” “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

There are challenges in efficiently managing or performing media management operations on typical memory devices. Certain memory systems control the read threshold voltage that is used to read data from the memory components and/or individual WLs of the memory components based on a program temperature and/or other criteria (e.g., RBER). For example, when reading data from the memory components, the memory controller can access a predetermined read threshold voltage associated with the level and/or block from which the data is being read. Using that predetermined read threshold, the memory controller can then read the data from the block. In some cases, the predetermined threshold voltage results in a larger than expected RBER. To reduce the number of errors resulting from read operations, certain memory controllers apply a read threshold computation process (e.g., read level correction process) or method, such as a valley track process, to compute more accurate read threshold voltages. The valley track process involves sampling the data from the cell of the memory block at multiple nearby read threshold voltages. The valley track process takes a great deal of time, which degrades performance of the memory sub-system.

These read threshold voltages, determined using the valley track process, can be selected relative to the predetermined read threshold voltage. The read threshold voltage that results in the smallest RBER can be selected and associated with that memory component for reading the data. When a subsequent read operation is received for the same or another block that may be physically adjacent to the previously read block, the memory controller can again perform the valley track process to compute/determine the optimal read threshold voltage. The need to reperform the valley track operations each time data is read from a given portion of the memory is incredibly inefficient and wastes a great deal of time since the valley track process takes time and degrades performance. This reduces the overall capabilities and quality of the memory sub-system beyond what may be needed and creates significant inefficiencies and wastes resources.

Certain memory controllers perform BF scan operations as an alternative to the valley track process or in addition to performing the valley track process. BF scan operations involve associating a set of blocks programmed within the same specified time interval and/or at the same temperature with a set of read levels. A BF scan can read or sample data from one of the blocks and adjust the set of read levels associated with the BF based on that sampled data. A BF scan is usually performed at specified time intervals and can be used to coarsely adjust the read levels. The accuracy of finding the optimal read levels using the BF scan is usually lower than the valley track process. Waiting for the coarse adjustment to the read levels performed using the BF scan can cause charges stored to the corresponding portions of the memory components to shift beyond repair of the BF scan. This can result in the need to perform valley track operations, which can increase read times and create significant inefficiencies and waste of resources.

Aspects of the present disclosure address the above and other deficiencies by providing a memory controller that can proactively triggers performing the valley track process or BF scan responsive to RBER associated with read data transgressing an RBER threshold. Namely, the memory sub-system controller can select between either performing valley track operations or BF scan operations as the read level correction process in response to the RBER of data read from a first portion of the memory components transgressing the RBER threshold. Namely, rather than waiting to perform the BF scan at previously scheduled periodic intervals or the valley track operations when the RBER is much greater than the RBER threshold, the controller can actively trigger performing one of these processes in response to the RBER transgressing the threshold. This enables the controller to read data from a second portion of the memory sub-system with adjusted read levels resulting from prior read operations accurately. This ensures that performance of the memory system remains optimal by controlling when complex read threshold voltage computation operations (e.g., valley track operations) and BF scan operations are performed. This improves the overall efficiency of operating the memory sub-system and reduces memory resource consumption.

In some examples, the memory controller reads a first portion of data from a first portion of the set of memory components using a set of read threshold levels. The memory controller determines a RBER associated with the data read from the first portion of the set of memory components and determines that the RBER associated with the data read from the first portion transgresses a threshold RBER. In some cases, this determination can be made by a low-density parity coding (LDPC) decoder and communicated to the memory controller as an interrupt or other signal. The memory controller selects an individual read level correction process from a plurality of read level correction processes to adjust the set of read threshold levels in response to determining that the RBER associated with the data read from the first portion transgresses the threshold RBER. The memory controller reads a second portion of data from a second portion of the set of memory components using the set of read threshold levels adjusted based on the selected individual read level correction process.

The first portion of the set of memory components can include a first block of an individual memory component and the second portion of the set of memory components can include a second block of the individual memory component. In some cases, the controller determines that the second portion of the set of memory components is within a threshold physical proximity to the first portion of the set of memory components. The set of read threshold levels associated with the second portion of the set of memory components can be adjusted in response to determining that the second portion of the set of memory components is within the threshold physical proximity to the first portion of the set of memory components.

The plurality of read level correction processes can include a valley track process and a BF scan process. In some cases, the valley track process adjusts the set of read threshold levels by performing operations including accessing a predetermined read threshold voltage and sampling data at different read threshold voltages relative to the predetermined read threshold voltage. The valley track process selects one or more threshold voltages from the different read threshold voltages based on an error rate associated with the sampled data.

In some examples, the BF scan process performs operations including storing a table that maps a plurality of portions of the set of memory components to respective sets of read threshold voltages based on relative program times of the plurality of portions. A first set of portions of the set of memory components includes a first plurality of portions of the set of memory components that have each been programmed within a first time period and a second set of portions of the set of memory components includes a second plurality of portions of the set of memory components that have each been programmed within a second time period. The BF scan process accesses, from the table, an individual set of read threshold voltages corresponding to the first portion of the set of memory components to read the first portion of data. The memory controller associates the first set of portions with a first set of read threshold voltages and associates the second set of portions with a second set of read threshold voltages.

The memory controller adjusts the read threshold voltages associated with one or more of the plurality of portions of the set of memory components in response to performing the BF scan process. In some cases, the controller periodically performs the BF scan process at specified time intervals and triggers performing the BF scan process between the specified time intervals in response to selecting the BF scan process as the individual read level correction process.

In some examples, the RBER is determined in response to applying an LDPC decoder to the first portion of the data. In some cases, the LDPC decoder determines that the RBER associated with the data read from the first portion transgresses the threshold RBER and in response to determining by the LDPC decoder that the RBER associated with the data read from the first portion transgresses the threshold RBER, transmits an interrupt to the at least one processing device including an indication that the data read from the first portion transgresses the threshold RBER.

The second portion of the set of memory components can be within a same BF of a plurality of BFs as the first portion of the set of memory components. Each BF of the plurality of BFs can represent portions of the set of memory components that were programmed with data within a same specified time interval. In some cases, the controller determines that the RBER associated with the data read from the second portion transgresses the threshold RBER and selects a different read level correction process from the plurality of read level correction processes to adjust the set of read threshold levels in response to determining that the RBER associated with the data read from the second portion transgresses the threshold RBER. The memory controller reads a third portion of data from a third portion of the set of memory components using the set of read threshold levels adjusted based on the different read level correction process.

In some cases, the controller determines that the RBER associated with the data read from the third portion transgresses the threshold RBER and selects the individual read level correction process from the plurality of read level correction processes to adjust the set of read threshold levels in response to determining that the RBER associated with the data read from the third portion transgresses the threshold RBER. The controller reads a fourth portion of data from a fourth portion of the set of memory components using the set of read threshold levels adjusted based on the individual read level correction process.

The memory controller can prevent periodically performing a BF scan process at specified time intervals and can trigger the BF scan process in response to selecting the BF scan process as the individual read level correction process. In some examples, the controller determines that the first portion of the set of memory components is in an individual BF of a plurality of BFs and stores a count associated with the individual BF representing a number of times that one or more portions of data read from one or more portions associated with the individual BF resulted in the RBER transgressing the threshold RBER. The controller triggers performing of the individual read level correction process in response to determining that the count transgresses a threshold value.

The memory controller computes the threshold RBER based on a weighted average of target RBER values associated with a first set of word lines associated with performance that is greater than a threshold performance value, a second set of word lines associated with performance that is less than the threshold performance value, and a third set of other word lines. In some cases, the individual read level correction process is prevented from being performed in response to determining that a cross temperature or extreme temperature signal is asserted.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing environment 100 including a memory sub-system 110, in accordance with some examples of the present disclosure. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies). Each memory die can include a plurality of planes in which data can be stored or programmed.

In some examples, the first memory component 112A including (a word line (WL), a word line group (WLG), a block, portion, or page of the first memory component 112A), or group of memory components including the first memory component 112A can be associated with a first reliability (capability) grade, value, measure, or lifetime program-erase count (PEC). The terms “reliability grade,” “value,” and “measure” are used interchangeably throughout and can have the same meaning. The second memory component 112N (a WL, a WLG, a block, portion, or page of the second memory component 112N) or group of memory components including the second memory component 112N can be associated with a second reliability (capability) grade, value, measure, or lifetime PEC. In some examples, each memory component 112A to 112N can store respective configuration data that specifies the respective reliability grade and lifetime PEC and current PEC. In some examples, a memory or register can be associated with all of the memory components 112A to 112N and can store a table that maps different groups, bins, or sets of the memory components 112A to 112N to respective reliability grades, lifetime PEC values, read threshold voltages, program (write) temperatures, and/or current PEC values.

In some examples, a memory or register can be associated with all of the memory components 112A to 112N and can store a table that maps a first set of portions of the memory components 112A to 112N that have been programmed within a same first threshold time period (and/or at a same range of temperatures and/or are within a first threshold physical proximity to each other) with a first set of read threshold voltages, and a second set of portions of the memory components 112A to 112N that have been programmed within a same second threshold time period (and/or at a same range of temperatures and/or are within a second threshold physical proximity to each other) with a second set of read threshold voltages. These are referred to as different BFs. Namely, the first set of portions can be referred to as a first BF and the second set of portions can be referred to as a second BF. A media operations manager 122 can periodically scan for different sets of the portions. For example, the first BF can correspond to a first set of bins that are scanned every 20 minutes for the need to update the associated read threshold voltages. The second BF can correspond to a second set of bins that are scanned every 360 minutes for the need to update the associated read threshold voltages. The first set of bins can represent data that was programmed less recently than the second set of bins or vice versa. These intervals for when the BFs are scanned are usually fixed.

In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, and a Universal Flash Storage (UFS) drive. Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a USB interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components. An example of non-volatile memory components includes a NAND-type flash memory and/or a (3D) NAND flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both a SLC portion and a MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory. In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative-or (NOR) flash memory, electrically erasable programmable read-only memory (EEPROM), and a cross-point array of non-volatile memory cells.

A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. For example, a single first row that spans a first set of the pages or blocks of the memory components 112A to 112N can correspond to or be grouped as a first block stripe, and a single second row that spans a second set of the pages or blocks of the memory components 112A to 112N can correspond to or be grouped as a second block stripe.

A memory sub-system controller 115 can communicate with the memory components 112A to 112N to perform memory operations such as reading data, writing data, or erasing data at the memory components 112A to 112N and other such operations. The memory sub-system controller 115 can communicate with the memory components 112A to 112N to perform various memory management operations, such as different scan rates, different scan frequencies, different wear leveling, different read disturb management, garbage collection operations, different near miss ECC operations, and/or different dynamic data refresh.

The memory sub-system controller 115 can include hardware such as one or more integrated circuits and/or discrete components, a buffer memory, or a combination thereof. The memory sub-system controller 115 can be a microcontroller, special-purpose logic circuitry (e.g., a field programmable gate array (FPGA), an application specific integrated circuit (ASIC), etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some embodiments, the local memory 119 can include memory registers storing memory pointers, fetched data, and so forth. The local memory 119 can also include ROM for storing microcode. While the example memory sub-system 110 in FIG. 1 has been illustrated as including the memory sub-system controller 115, in another example of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112A to 112N. The configuration data can describe the lifetime PEC values and/or reliability grades associated with different groups of the memory components 112A to 112N and/or different WLs, WLGs, and/or blocks within each of the memory components 112A to 112N.

The memory sub-system controller 115 can be responsible for other memory management operations, such as wear leveling operations, garbage collection operations, error detection and ECC operations, encryption operations, caching operations, and address translations. The memory sub-system controller 115 can further include host interface circuitry to communicate with the host system 120 via the physical host interface. The host interface circuitry can convert the commands received from the host system 120 into command instructions to access the memory components 112A to 112N as well as convert responses associated with the memory components 112A to 112N into information for the host system 120. In some cases, the memory sub-system controller 115 can implement an LDPC decoder for decoding data retrieved from the set of memory components 112A to 112N. In some cases, the memory sub-system controller 115 can access the LDPC that is implemented external to the memory sub-system controller 115 (e.g., by the host system 120) decoder for decoding data retrieved from the set of memory components 112A to 112N.

The memory sub-system 110 can also include additional circuitry or components that are not illustrated. In some examples, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which is are raw memory devices combined with a local embedded controller (e.g., local media controllers) for memory management within the same memory device package. Any one of the memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

The memory sub-system controller 115 can include a media operations manager 122. The media operations manager 122 can be configured to selectively perform one or more read level correction processes, such as the valley track process and/or the BF scan process, based on RBER determined based on data read from a first portion of the set of memory components 112A to 112N. For example, the media operations manager 122 can receive a request to read data from the first portion. In response, the media operations manager 122 can read the data from the first portion and provide the data or signal representing the data to the LDPC decoder. The LDPC decoder can determine the RBER associated with the data or signal representing the data and can compare that RBER to an RBER threshold. In response to determining that the RBER transgresses the RBER threshold (e.g., exceeds the RBER threshold), the LDPC decoder can trigger an interrupt informing the memory sub-system controller 115 that the RBER of the data read from the first portion transgresses the RBER threshold. The RBER threshold can be set to a value that still allows the LDPC decoder to correctly decode the data but may be indicative that read level correction may be needed. Namely, while the LDPC decoder can correctly decode the data stored in the first portion, the LDPC can still trigger the interrupt in response to determining that the RBER of this data transgresses the RBER threshold.

In response, the memory sub-system controller 115 can perform the valley track process to correct read levels associated with a BF that includes the first portion and/or perform the BF scan before the next time interval for performing the BF scan for the bin that includes the first portion is reached. In this way, the read levels associated with reading a second portion of the set of memory components 112A to 112N can be adjusted and improved without having to wait for the BF scan to be performed at the scheduled time interval or without having to unnecessarily perform the valley track process for reading the data from the second portion.

In some cases, the memory sub-system controller 115 can perform the valley track process to correct the read levels when a first interrupt is first received from the LDPC decoder in association with the BF that includes the first portion of the set of memory components 112A to 112N. Then, the memory sub-system controller 115 can perform the BF scan to correct the read levels when a second interrupt is received from the LDPC decoder in association with the BF that includes a second portion and the first portion of the set of memory components 112A to 112N. Finally, the memory sub-system controller 115 can perform the valley track process to correct the read levels when a third interrupt is received from the LDPC decoder in association with the BF that includes a third portion, the second portion, and the first portion of the set of memory components 112A to 112N.

In some examples, the media operations manager 122 can comprise logic (e.g., a set of transitory or non-transitory machine instructions, such as firmware) or one or more components that cause the media operations manager 122 to perform operations described herein. The media operations manager 122 can comprise a tangible or non-tangible unit capable of performing operations described herein. Further details with regards to the operations of the media operations manager 122 are described below.

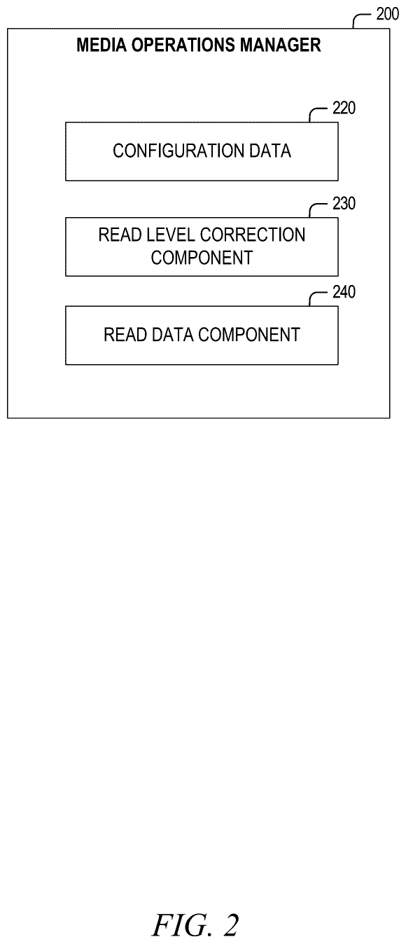

FIG. 2 is a block diagram of an example media operations manager 200 (corresponding to media operations manager 122), in accordance with some implementations of the present disclosure. As illustrated, the media operations manager 200 includes configuration data 220, a read level correction component 230, and a read data component 240. In some cases, the media operations manager 200 can differ in components or arrangement (e.g., less or more components) from what is illustrated in FIG. 2.

The configuration data 220 accesses and/or stores configuration data associated with the memory components 112A to 112N. In some examples, the configuration data 220 is programmed into the media operations manager 200. For example, the media operations manager 200 can communicate with the memory components 112A to 112N to obtain the configuration data and store the configuration data 220 locally on the media operations manager 122. In some examples, the media operations manager 122 communicates with the host system 120. The host system 120 receives input from an operator or user that specifies parameters including read threshold voltages of different WLs, WLGs, bins, groups, blocks, block stripes, memory dies and/or sets of the memory components 112A to 112N. The media operations manager 122 receives configuration data from the host system 120 and stores the configuration data in the configuration data 220.

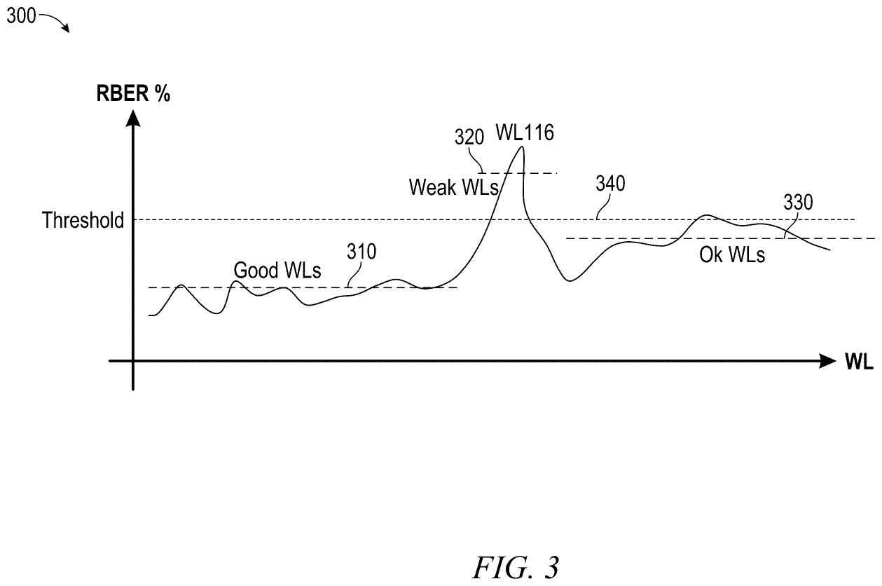

The configuration data 220 can store a value for the RBER threshold that is used to trigger interrupts by the LDPC decoder. The RBER threshold can be computed based on known or target RBER values associated with different WL or WLG, as shown in the diagram 300 of FIG. 3. For example, during manufacture of the memory sub-system 110, a first set of WLs 310 can be identified as having associated target RBER values that are below a specified value (e.g., these are WLs that are associated with better performance than all other WLs). A first set of target RBER values can be obtained that are associated with the first set of WLs 310. A second set of WLs 320 can be identified as having associated target RBER values that are above another specified value (e.g., these are WLs that are associated with worse performance than all other WLs). A second set of target RBER values can be obtained that are associated with the second set of WLs 320. The remaining set of WLs 330 (which can exclude certain WLs known to be defective or associated with very poor performance) can be identified. A third set of target RBER values can be obtained that are associated with the third set of WLs 330.

An RBER threshold 340 can be computed as a weighted average of the first, second and third target RBER values. For example, a first weight can be associated with the first set of target RBER values, a second weight can be associated with the second set of target RBER values, and a third weight can be associated with the third set of target RBER values. The first weight can be smaller than the second and third weights. The second weight can be greater than the third weight. An average can be computed based on the weighted target RBER values and stored as the table in the configuration data 220.

The configuration data 220 can store a table that maps a first set of portions (e.g., a first BF and/or bin) of the memory components 112A to 112N that have been programmed within a same first threshold time period (and/or at a same range of temperatures and/or are within a first threshold physical proximity to each other) with a first set of read threshold voltages, and a second set of portions (e.g., a second BF and/or bin) of the memory components 112A to 112N that have been programmed within a same second threshold time period (and/or at a same range of temperatures and/or are within a second threshold physical proximity to each other) with a second set of read threshold voltages.

For example, a table can be generated and stored as part of the configuration data 220 based on the temperature ranges of the memory sub-system 110 when data is programmed to different portions of the memory sub-system 110. In some cases, the table can store the write temperature associated with each of the different portions of the memory sub-system 110. The media operations manager 200 can determine a read temperature associated with the memory sub-system 110 when a read request is received. The table can include a list of groups along with indications of the portions (e.g., blocks) within each group. In some examples, at a first point in time, data can first be programmed to a first portion of the memory components 112A to 112N, such as a first block (block A) when the memory components 112A to 112N are operating at a first range of temperatures. This first block can be stored in association with a first group of the list of groups in the table.

At a second point in time (which can be within the same individual time period as that used to store the first block), data can be programmed to a second portion of the memory components 112A to 112N, such as a second block (block B) when the memory components 112A to 112N are operating at a second range of temperatures of the set of different temperatures. This second block can be stored in association with a second group of the list of groups in the table or with the first group. At a third point in time (which can be within the individual time period), data can be programmed to a third portion of the memory components 112A to 112N, such as a third block (block C) when the memory components 112A to 112N are operating at the first range of temperatures. In such cases, the third block can be stored in association with the first group of the list of groups in the table. Namely, the third block can be grouped together with the first block because both blocks were programmed at the same temperature range and were programmed within the individual time period and/or are within a threshold physical proximity to each other. If the individual time period has elapsed and a new time period has begun, a new memory block can be grouped with a different set of groups of the memory blocks associated with the new time period. These groups stored in the table represent different BFs. A BF scan can update the read levels associated with a particular BF or group.

The first group can be associated with a first set of read threshold voltages. The first set of read threshold voltages can define different read threshold voltage values for different levels of an MLC cell of the memory components 112A to 112N. A second group can be associated with a second set of read threshold voltages. The second set of read threshold voltages can define different read threshold voltage values for different levels of an MLC cell of the memory components 112A to 112N. The first set of read threshold voltages can be the same in part or totally different from the second set of read threshold voltages.

The read level correction component 230 can receive a request to read data from an individual portion of the memory components 112A to 112N. In response, the read level correction component 230 can communicate with the configuration data 220 to determine which group or zone that individual portion belongs to. The read level correction component 230 can instruct the read data component 240 to read the data from the individual portion according to a read threshold voltage stored in the threshold voltages in association with the group that includes the individual portion of the memory components 112A to 112N.

The read level correction component 230 can determine the RBER associated with reading the data according to the read threshold voltage stored in the threshold voltages of the table. The read level correction component 230 can implement an LDPC decoder. The read level correction component 230 can compute the RBER using the LDPC decoder for a first portion of data read from a first portion of the set of memory components 112A to 112N. The read level correction component 230 can retrieve the RBER threshold stored in the configuration data 220. The read level correction component 230 can compare the RBER determined by the LDPC decoder to the RBER threshold. The read level correction component 230 (e.g., the LDPC decoder) can determine that the RBER of the data transgresses the RBER threshold. In such cases, the LDPC decoder (e.g., the read level correction component 230) can transmit an interrupt to the read data component 240. The interrupt can inform the read data component 240 (or other component in the media operations manager 200) that the data read from the first portion of the set of memory components 112A to 112N was successfully decoded but had an RBER that transgressed the RBER threshold.

In some examples, in response to receiving the interrupt from the LDPC decoder, the read data component 240 can immediately select and perform an individual read error correction process. For example, the read data component 240 can immediately trigger performing the BF scan operations to update the read values associated with the BF that includes the first portion of the set of memory components 112A to 112N. Alternatively, the read data component 240 can trigger performing the valley track process to update the read values associated with the BF that includes the first portion of the set of memory components 112A to 112N. This way, rather than waiting for the next period that triggers the BF scan for the BF or bin that includes the first portion of the set of memory components 112A to 112N, the memory sub-system controller 115 can immediately perform the BF scan.

The read level correction component 230 can receive a request to read data from a second portion of the set of memory components 112A to 112N. Similar to reading the data from the first portion of the set of memory components 112A to 112N, the read level correction component 230 can read and decode the data using the LDPC decoder. The data can be read with the read levels that were updated in response to previously receiving the interrupt from the LDPC decoder (e.g., the interrupt triggered based on the RBER of the data read from the first portion of the set of memory components 112A to 112N transgressing the threshold). The read level correction component 230 can determine the RBER associated with reading the data according to the read threshold voltage stored in the threshold voltages of the table for the second portion of the set of memory components 112A to 112N.

The read level correction component 230 can compute the RBER using the LDPC decoder for a second portion of data read from the second portion of the set of memory components 112A to 112N. The read level correction component 230 can retrieve the RBER threshold stored in the configuration data 220. The read level correction component 230 can compare the RBER determined by the LDPC decoder to the RBER threshold. The read level correction component 230 (e.g., the LDPC decoder) can determine that the RBER of the data transgresses the RBER threshold. In such cases, the LDPC decoder (e.g., the read level correction component 230) can again transmit an interrupt to the read data component 240. The interrupt can inform the read data component 240 (or other component in the media operations manager 200) that the data read from the second portion of the set of memory components 112A to 112N was successfully decoded but had an RBER that transgressed the RBER threshold.

In response to receiving the additional interrupt from the LDPC decoder, the read data component 240 can immediately select and perform an individual read error correction process. For example, the read data component 240 can immediately trigger performing the BF scan operations to update the read values associated with the BF that includes the second portion of the set of memory components 112A to 112N. The BF can be the same as that which includes the first portion or can be different. Alternatively, the read data component 240 can trigger performing the valley track process to update the read values associated with the BF that includes the second portion of the set of memory components 112A to 112N. In some cases, if valley track was selected and performed in response to the first interrupt (resulting from decoding the data read from the first portion of the set of memory components 112A to 112N), the read data component 240 selects and performs the BF scan to update the read values associated with the BF of the second portion of the set of memory components 112A to 112N. If BF scan was selected and performed in response to the first interrupt (resulting from decoding the data read from the first portion of the set of memory components 112A to 112N), the read data component 240 selects and performs the valley track process to update the read values associated with the BF of the second portion of the set of memory components 112A to 112N. The read data component 240 can alternate between performing BF scans and performing valley track and/or other read level correction processes.

The read level correction component 230 can receive a request to read data from a third portion of the set of memory components 112A to 112N. Similar to reading the data from the first and second portions of the set of memory components 112A to 112N, the read level correction component 230 can read and decode the data using the LDPC decoder. The data can be read with the read levels that were updated in response to previously receiving the interrupt from the LDPC decoder (e.g., the second or additional interrupt triggered based on the RBER of the data read from the second portion of the set of memory components 112A to 112N transgressing the threshold). The read level correction component 230 can determine the RBER associated with reading the data according to the read threshold voltage stored in the threshold voltages of the table for the second portion of the set of memory components 112A to 112N.

The read level correction component 230 can compute the RBER using the LDPC decoder for a third portion of data read from the third portion of the set of memory components 112A to 112N. The read level correction component 230 can retrieve the RBER threshold stored in the configuration data 220. The read level correction component 230 can compare the RBER determined by the LDPC decoder to the RBER threshold. The read level correction component 230 (e.g., the LDPC decoder) can determine that the RBER of the data transgresses the RBER threshold. In such cases, the LDPC decoder (e.g., the read level correction component 230) can again transmit an interrupt (e.g., a third interrupt) to the read data component 240. The third interrupt can inform the read data component 240 (or other component in the media operations manager 200) that the data read from the third portion of the set of memory components 112A to 112N was successfully decoded but had an RBER that transgressed the RBER threshold.

In response to receiving the additional interrupt from the LDPC decoder, the read data component 240 can immediately select and perform an individual read error correction process. For example, the read data component 240 can immediately trigger performing the BF scan operations to update the read values associated with the BF that includes the third portion of the set of memory components 112A to 112N. The BF can be the same as that which includes the first and second portions or can be different. Alternatively, the read data component 240 can trigger performing the valley track process to update the read values associated with the BF that includes the third portion of the set of memory components 112A to 112N. In some cases, if valley track was selected and performed in response to the second interrupt (resulting from decoding the data read from the second portion of the set of memory components 112A to 112N), the read data component 240 selects and performs the BF scan to update the read values associated with the BF of the third portion of the set of memory components 112A to 112N. If BF scan was selected and performed in response to the second interrupt (resulting from decoding the data read from the second portion of the set of memory components 112A to 112N), the read data component 240 selects and performs the valley track process to update the read values associated with the BF of the second portion of the set of memory components 112A to 112N.

In some cases, the read level correction component 230 maintains a count of interrupts in association with the different groups or BFs that are stored. The count can represent the quantity or number of times that the BF has received an interrupt from the LDPC in response to RBER of data read from a portion that is in the BF transgressing the RBER threshold. For example, the LDPC can generate an interrupt in response to determining that the RBER associated with the first portion of the set of memory components 112A to 112N transgresses the RBER threshold. The read level correction component 230 can identify the BF that includes the first portion of the set of memory components 112A to 112N and increments the count of interrupts value stored in association with that BF.

In some examples, the read data component 240 can condition performing the BF scan for a particular BF based on the currently stored count associated with the BF. For example, the read data component 240 can receive the interrupt from the LDPC identifying a particular BF. The read data component 240 can update a count associated with the particular BF and determine that the updated count fails to transgress a minimum count value or count value threshold. In such cases, the read data component 240 prevents performing the BF scan or valley track. Also, the read data component 240 can determine that a scheduled time period for performing a BF scan for the particular BF has been reached. At this point, the read data component 240 can determine that the current count fails to transgress a minimum count value or count value threshold. In such cases, the read data component 240 prevents performing the BF scan at the scheduled time period and can condition performing the BF scan at the next scheduled time period (e.g., 20 minutes later).

In some examples, the read data component 240 can update a count associated with the particular BF in response to receiving the interrupt from the LDP C decoder. The read data component 240 can determine that the updated count transgresses the minimum count value or count value threshold. In such cases, the read data component 240 performs the BF scan or valley track to update the set of read levels associated with the BF and clears the count associated with the BF.

In some examples, in response to receiving the interrupt, the read data component 240 can access a queue of read requests. The read data component 240 can condition performing the read level correction process or select which read level correction process to apply based on the queue of read requests. Specifically, the read data component 240 can determine whether the next read request in the queue is a read to be performed to a portion of the set of memory components that is sequential and adjacent to the portion that triggered the interrupt. In such cases, the read data component 240 can perform the BF scan in response to the interrupt. Alternatively, or in addition, the read data component 240 can cause the valley track to be performed when performing the next read request that is in the queue to read the adjacent portion of the set of memory components 112A to 112N.

In some cases, the valley track process can include a bin update (e.g., a block family error avoidance (BFEA)) associated with a BF scan operation if the bin associated with the portion that triggered the interrupt was mis-calibrated by more than a certain amount. If the BFEA bin is higher than a certain value, the corresponding block can be marked for background refresh operations. In some examples, the read data component 240 can determine that the next read in the queue is associated with reading a portion of the set of memory components 112A to 112N that is not adjacent to the current portion that was read and resulted in the interrupt being triggered. In such cases, the read data component 240 can determine that the next read is a random read and can mark that block for background handling, such as media scan operations.

In some cases, the read data component 240 can prevent performing BF scan operations in response to determining that the cross-temperature or current temperature of the memory sub-system 110 transgresses a threshold value. In these circumstances, BF scan operations can be avoided when the memory sub-system 110 is temporarily operating under extreme temperatures. In some cases, changing the bin/read levels can be allowed when the memory sub-system 110 is temporarily operating under extreme temperatures.

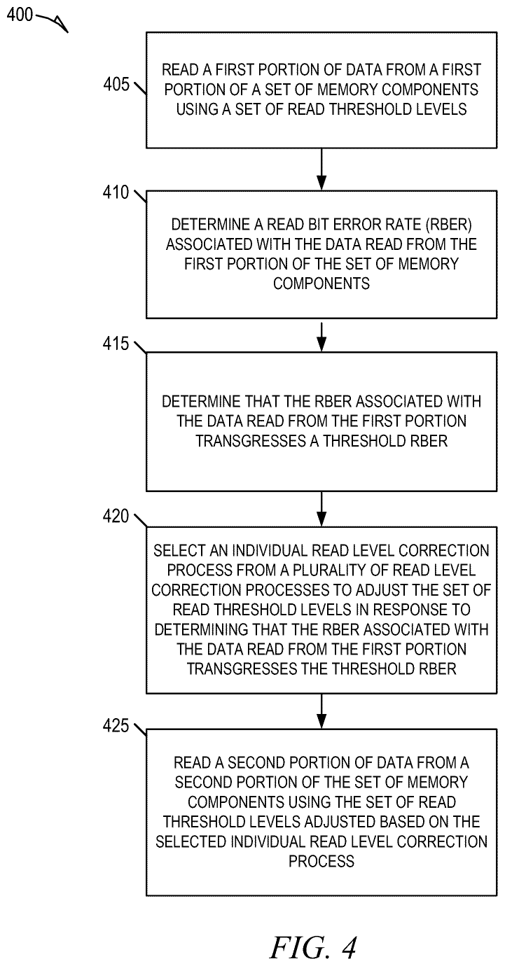

FIG. 4 is a flow diagram of an example method 400 to selectively compute a read threshold voltage for certain portions of a memory component, in accordance with some examples. The method 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some embodiments, the method 400 is performed by the media operations manager 122 of FIG. 1. Although the processes are shown in a particular sequence or order, unless otherwise specified, the order of the processes can be modified. Thus, the illustrated techniques should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 4, the method (or process) 400 begins at operation 405, with a media operations manager 122 of a memory sub-system (e.g., memory sub-system 110) receiving a request to read data from a first portion of a set of memory components. Then, at operation 410, the media operations manager 122 of the memory sub-system determines a RBER associated with the data read from the first portion of the set of memory components. Thereafter, at operation 415, the media operations manager 122 determines that the RBER associated with the data read from the first portion transgresses a threshold RBER. Then, at operation 420, the media operations manager 122 selects an individual read level correction process from a plurality of read level correction processes to adjust the set of read threshold levels in response to determining that the RBER associated with the data read from the first portion transgresses the threshold RBER and, at operation 425, reads a second portion of data from a second portion of the set of memory components using the set of read threshold levels adjusted based on the selected individual read level correction process.

In view of the disclosure above, various examples are set forth below. It should be noted that one or more features of an example, taken in isolation or combination, should be considered within the disclosure of this application.

Example 1: A system comprising: a set of memory components of a memory sub-system; and at least one processing device operatively coupled to the set of memory components, the at least one processing device being configured to perform operations comprising: reading a first portion of data from a first portion of the set of memory components using a set of read threshold levels; determining a read bit error rate (RBER) associated with the data read from the first portion of the set of memory components; determining that the RBER associated with the data read from the first portion transgresses a threshold RBER; selecting an individual read level correction process from a plurality of read level correction processes to adjust the set of read threshold levels in response to determining that the RBER associated with the data read from the first portion transgresses the threshold RBER; and reading a second portion of data from a second portion of the set of memory components using the set of read threshold levels adjusted based on the selected individual read level correction process.

Example 2. The system of Example 1, wherein the first portion of the set of memory components comprises a first block of an individual memory component and the second portion of the set of memory components comprises a second block of the individual memory component.

Example 3. The system of any one of Examples 1-2, the operations comprising: determining that the second portion of the set of memory components is within a threshold physical proximity to the first portion of the set of memory components, wherein the set of read threshold levels associated with the second portion of the set of memory components is adjusted in response to determining that the second portion of the set of memory components is within the threshold physical proximity to the first portion of the set of memory components.

Example 4. The system of any one of Examples 1-3, wherein the plurality of read level correction processes comprise a valley track process and a block family (BF) scan process.

Example 5. The system of Example 4, wherein the valley track process adjusts the set of read threshold levels by performing operations comprising: accessing a predetermined read threshold voltage; sampling data at different read threshold voltages relative to the predetermined read threshold voltage; and selecting one or more threshold voltages from the different read threshold voltages based on an error rate associated with the sampled data.

Example 6. The system of any one of Examples 4-5, wherein the BF scan process performs operations comprising: storing a table that maps a plurality of portions of the set of memory components to respective sets of read threshold voltages based on relative program times of the plurality of portions, wherein a first set of portions of the set of memory components comprises a first plurality of portions of the set of memory components that have each been programmed within a first time period, wherein a second set of portions of the set of memory components comprises a second plurality of portions of the set of memory components that have each been programmed within a second time period; and accessing, from the table, an individual set of read threshold voltages corresponding to the first portion of the set of memory components to read the first portion of data.

Example 7. The system of Example 6, the operations comprising: associating the first set of portions with a first set of read threshold voltages; and associating the second set of portions with a second set of read threshold voltages.

Example 8. The system of any one of Examples 6-7, the operations comprising: adjusting the read threshold voltages associated with one or more of the plurality of portions of the set of memory components in response to performing the BF scan process.

Example 9. The system of any one of Examples 6-8, the operations comprising: periodically performing the BF scan process at specified time intervals; and triggering performing the BF scan process between the specified time intervals in response to selecting the BF scan process as the individual read level correction process.

Example 10. The system of any one of Examples 1-9, wherein the RBER is determined in response to applying an LDPC decoder to the first portion of the data.

Example 11. The system of Example 10, the operations comprising: determining by the LDPC decoder that the RBER associated with the data read from the first portion transgresses the threshold RBER; and in response to determining by the LDPC decoder that the RBER associated with the data read from the first portion transgresses the threshold RBER, transmitting an interrupt to the at least one processing device comprising an indication that the data read from the first portion transgresses the threshold RBER.

Example 12. The system of any one of Examples 1-11, wherein the second portion of the set of memory components is within a same block family of a plurality of block families as the first portion of the set of memory components, each block family of the plurality of block families representing portions of the set of memory components that were programmed with data within a same specified time interval.

Example 13. The system of any one of Examples 1-12, the operations comprising: determining that the RBER associated with the data read from the second portion transgresses the threshold RBER; selecting a different read level correction process from the plurality of read level correction processes to adjust the set of read threshold levels in response to determining that the RBER associated with the data read from the second portion transgresses the threshold RBER; and reading a third portion of data from a third portion of the set of memory components using the set of read threshold levels adjusted based on the different read level correction process.

Example 14. The system of Example 13, the operations comprising: determining that the RBER associated with the data read from the third portion transgresses the threshold RBER; selecting the individual read level correction process from the plurality of read level correction processes to adjust the set of read threshold levels in response to determining that the RBER associated with the data read from the third portion transgresses the threshold RBER; and reading a fourth portion of data from a fourth portion of the set of memory components using the set of read threshold levels adjusted based on the individual read level correction process.

Example 15. The system of any one of Examples 1-14, the operations comprising preventing periodically performing a block family (BF) scan process at specified time intervals, the BF scan process being triggered in response to selecting the BF scan process as the individual read level correction process.

Example 16. The system of any one of Examples 1-15, the operations comprising: determining that the first portion of the set of memory components is in an individual block family (BF) of a plurality of block families; storing a count associated with the individual BF representing a number of times that one or more portions of data read from one or more portions associated with the individual BF resulted in the RBER transgressing the threshold RBER; and triggering performing of the individual read level correction process in response to determining that the count transgresses a threshold value.

Example 17. The system of any one of Examples 1-16, the operations comprising: computing the threshold RBER based on a weighted average of target RBER values associated with a first set of word lines associated with performance that is greater than a threshold performance value, a second set of word lines associated with performance that is less than the threshold performance value, and a third set of other word lines.

Example 18. The system of any one of Examples 1-17, wherein performing the individual read level correction process is prevented in response to determining that a cross temperature or extreme temperature signal is asserted.

Example 19. A method comprising: reading a first portion of data from a first portion of a set of memory components using a set of read threshold levels; determining a read bit error rate (RBER) associated with the data read from the first portion of the set of memory components; determining that the RBER associated with the data read from the first portion transgresses a threshold RBER; selecting an individual read level correction process from a plurality of read level correction processes to adjust the set of read threshold levels in response to determining that the RBER associated with the data read from the first portion transgresses the threshold RBER; and reading a second portion of data from a second portion of the set of memory components using the set of read threshold levels adjusted based on the selected individual read level correction process.

Example 20. A non-transitory computer-readable storage medium comprising instructions that, when executed by at least one processing device, cause the at least one processing device to perform operations comprising: reading a first portion of data from a first portion of a set of memory components using a set of read threshold levels; determining a read bit error rate (RBER) associated with the data read from the first portion of the set of memory components; determining that the RBER associated with the data read from the first portion transgresses a threshold RBER; selecting an individual read level correction process from a plurality of read level correction processes to adjust the set of read threshold levels in response to determining that the RBER associated with the data read from the first portion transgresses the threshold RBER; and reading a second portion of data from a second portion of the set of memory components using the set of read threshold levels adjusted based on the selected individual read level correction process.

Methods and computer-readable storage medium with instructions for performing any one of the above Examples.

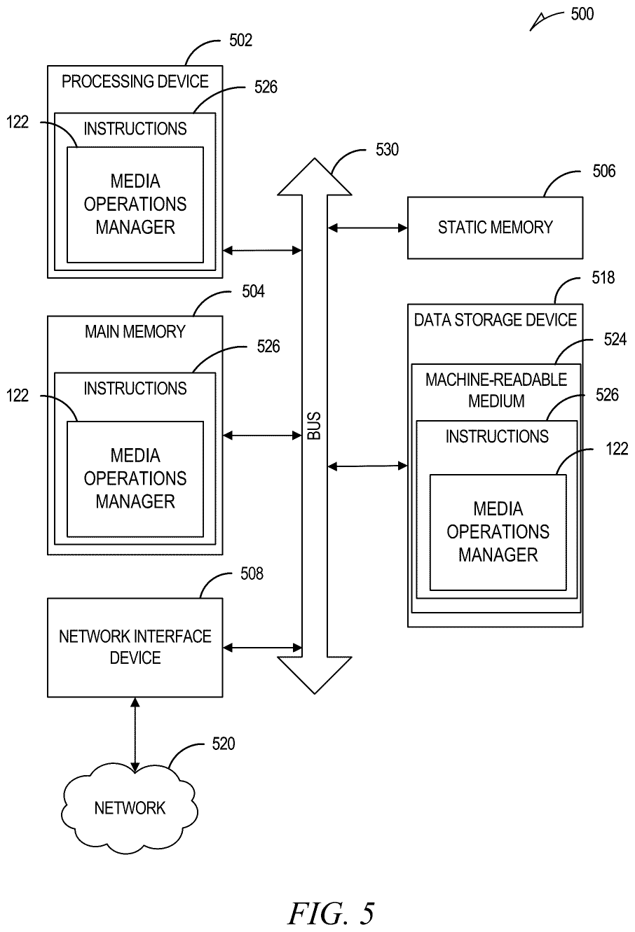

FIG. 5 illustrates an example machine in the form of a computer system 500 within which a set of instructions can be executed for causing the machine to perform any one or more of the methodologies discussed herein. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or Rambus DRAM (RDRAM), etc.), a static memory 506 (e.g., flash memory, static random access memory (SRAM), etc.), and a data storage system 518, which communicate with each other via a bus 530.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices such as an ASIC, a FPGA, a digital signal processor (DSP), a network processor, or the like. The processing device 502 is configured to execute instructions 526 for performing the operations and steps discussed herein. The computer system 500 can further include a network interface device 508 to communicate over a network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one example, the instructions 526 implement functionality corresponding to the media operations manager 122 of FIG. 1. While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; ROMs; RAMs; EPROMs; EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine-readable (e.g., computer-readable) storage medium such as a ROM, RAM, magnetic disk storage media, optical storage media, flash memory components, and so forth.

In the foregoing specification, examples of the disclosure have been described. It will be evident that various modifications can be made thereto without departing from the broader scope of the disclosure as set forth in the following claims. The specification and drawings are, accordingly, to be regarded in an illustrative sense rather than a restrictive sense.

What is claimed is:

1. A system comprising:
a set of memory components of a memory sub-system; and
at least one processing device operatively coupled to the set of memory components, the at least one processing device being configured to perform operations comprising:
reading a first portion of data from a first portion of the set of memory components using a set of read threshold levels;
determining a read bit error rate (RBER) associated with the data read from the first portion of the set of memory components;
determining that the RBER associated with the data read from the first portion transgresses a threshold RBER;
selecting an individual read level correction process from a plurality of read level correction processes to adjust the set of read threshold levels in response to determining that the RBER associated with the data read from the first portion transgresses the threshold RBER; and
reading a second portion of data from a second portion of the set of memory components using the set of read threshold levels adjusted based on the selected individual read level correction process.

2. The system of claim 1, wherein the first portion of the set of memory components comprises a first block of an individual memory component and the second portion of the set of memory components comprises a second block of the individual memory component.

3. The system of claim 1, the operations comprising:
determining that the second portion of the set of memory components is within a threshold physical proximity to the first portion of the set of memory components, wherein the set of read threshold levels associated with the second portion of the set of memory components is adjusted in response to determining that the second portion of the set of memory components is within the threshold physical proximity to the first portion of the set of memory components.

4. The system of claim 1, wherein the plurality of read level correction processes comprise a valley track process and a block family (BF) scan process.

5. The system of claim 4, wherein the valley track process adjusts the set of read threshold levels by performing operations comprising:
accessing a predetermined read threshold voltage;
sampling data at different read threshold voltages relative to the predetermined read threshold voltage; and
selecting one or more threshold voltages from the different read threshold voltages based on an error rate associated with the sampled data.

6. The system of claim 4, wherein the BF scan process performs operations comprising:
storing a table that maps a plurality of portions of the set of memory components to respective sets of read threshold voltages based on relative program times of the plurality of portions, wherein a first set of portions of the set of memory components comprises a first plurality of portions of the set of memory components that have each been programmed within a first time period, wherein a second set of portions of the set of memory components comprises a second plurality of portions of the set of memory components that have each been programmed within a second time period; and
accessing, from the table, an individual set of read threshold voltages corresponding to the first portion of the set of memory components to read the first portion of data.

7. The system of claim 6, the operations comprising:
associating the first set of portions with a first set of read threshold voltages; and
associating the second set of portions with a second set of read threshold voltages.

8. The system of claim 6, the operations comprising:
adjusting the read threshold voltages associated with one or more of the plurality of portions of the set of memory components in response to performing the BF scan process.

9. The system of claim 6, the operations comprising:
periodically performing the BF scan process at specified time intervals; and
triggering performing the BF scan process between the specified time intervals in response to selecting the BF scan process as the individual read level correction process.

10. The system of claim 1, wherein the RBER is determined in response to applying an LDPC decoder to the first portion of the data.

11. The system of claim 10, the operations comprising:
determining by the LDPC decoder that the RBER associated with the data read from the first portion transgresses the threshold RBER; and
in response to determining by the LDPC decoder that the RBER associated with the data read from the first portion transgresses the threshold RBER, transmitting an interrupt to the at least one processing device comprising an indication that the data read from the first portion transgresses the threshold RBER.

12. The system of claim 1, wherein the second portion of the set of memory components is within a same block family of a plurality of block families as the first portion of the set of memory components, each block family of the plurality of block families representing portions of the set of memory components that were programmed with data within a same specified time interval.

13. The system of claim 1, the operations comprising:
determining that the RBER associated with the data read from the second portion transgresses the threshold RBER;
selecting a different read level correction process from the plurality of read level correction processes to adjust the set of read threshold levels in response to determining that the RBER associated with the data read from the second portion transgresses the threshold RBER; and
reading a third portion of data from a third portion of the set of memory components using the set of read threshold levels adjusted based on the different read level correction process.

14. The system of claim 13, the operations comprising:
determining that the RBER associated with the data read from the third portion transgresses the threshold RBER;
selecting the individual read level correction process from the plurality of read level correction processes to adjust the set of read threshold levels in response to determining that the RBER associated with the data read from the third portion transgresses the threshold RBER; and
reading a fourth portion of data from a fourth portion of the set of memory components using the set of read threshold levels adjusted based on the individual read level correction process.

15. The system of claim 1, the operations comprising preventing periodically performing a block family (BF) scan process at specified time intervals, the BF scan process being triggered in response to selecting the BF scan process as the individual read level correction process.

16. The system of claim 1, the operations comprising:
determining that the first portion of the set of memory components is in an individual block family (BF) of a plurality of BFs;
storing a count associated with the individual BF representing a number of times that one or more portions of data read from one or more portions associated with the individual BF resulted in the RBER transgressing the threshold RBER; and
triggering performing of the individual read level correction process in response to determining that the count transgresses a threshold value.

17. The system of claim 1, the operations comprising:
computing the threshold RBER based on a weighted average of target RBER values associated with a first set of word lines associated with performance that is greater than a threshold performance value, a second set of word lines associated with performance that is less than the threshold performance value, and a third set of other word lines.

18. The system of claim 1, wherein performing the individual read level correction process is prevented in response to determining that a cross temperature or extreme temperature signal is asserted.

19. A method comprising:
reading a first portion of data from a first portion of a set of memory components using a set of read threshold levels;
determining a read bit error rate (RBER) associated with the data read from the first portion of the set of memory components;
determining that the RBER associated with the data read from the first portion transgresses a threshold RBER;
selecting an individual read level correction process from a plurality of read level correction processes to adjust the set of read threshold levels in response to determining that the RBER associated with the data read from the first portion transgresses the threshold RBER; and
reading a second portion of data from a second portion of the set of memory components using the set of read threshold levels adjusted based on the selected individual read level correction process.

20. A non-transitory computer-readable storage medium comprising instructions that, when executed by at least one processing device, cause the at least one processing device to perform operations comprising:
reading a first portion of data from a first portion of a set of memory components using a set of read threshold levels;
determining a read bit error rate (RBER) associated with the data read from the first portion of the set of memory components;
determining that the RBER associated with the data read from the first portion transgresses a threshold RBER;
selecting an individual read level correction process from a plurality of read level correction processes to adjust the set of read threshold levels in response to determining that the RBER associated with the data read from the first portion transgresses the threshold RBER; and
reading a second portion of data from a second portion of the set of memory components using the set of read threshold levels adjusted based on the selected individual read level correction process.
